(19) United States
(12) Patent Application Publication
(10) Pub. No.: US 2015/0255632 A1
(43) Pub. Date: Sep. 10, 2015

(54) SOLAR CELL ELECTRICALLY CONDUCTIVE STRUCTURE AND METHOD

(71) Applicant: Xjet Ltd., Rehovot (IL)

(72) Inventors: Eliahu M. Kritchman, Tel Aviv (IL); Ofir Baharav, Shanghai (CN); Michael Dovrat, Modi'in (IL); Lior Lavid, Rishon Lezion (IL); Hanan Gothait, Rehovot (IL)

(73) Assignee: Xjet Ltd., Rehovot (IL)

(21) Appl. No.: 14/404,455

(22) PCT Filed: May 28, 2013
(86) PCT No.: PCT/IL2013/050453

§ 371 Date: Nov. 27, 2014

Related U.S. Application Data
(60) Provisional application No. 61/652,270, filed on May 28, 2012.
(60) Provisional application No. 61/675,385, filed on Jul. 25, 2012.

(51) Int. Cl. H01L 31/02; H01L 31/0224

(52) U.S. Cl. CPC H01L 31/0201; H01L 31/022433

(57) ABSTRACT

Some aspects of the invention are related to a solar cell, for producing electricity from solar radiation. The solar cell may include a substrate, for example, polycrystalline silicon and an electrically conductive structure disposed on the substrate. The electrically conductive structure may include a bus bar and one or more finger electrodes positioned such that at least a portion of a finger electrode overlaps the bus bar.

### FIELD OF THE INVENTION

The present invention relates to semiconductor fabrication. More particularly, the present invention relates to deposition of contacts on semiconductor substrates.

### BACKGROUND

A solar cell (also know as, photovoltaic solar cell) typically includes a substrate in the form of a wafer of a semiconductor material (e.g. silicon) with pn junctions formed near its front side. When the front side of the photovoltaic cell is exposed to light, such as solar radiation, an electric current may be produced in the junctions. This current may be collected by electrical contacts that are deposited on the front (light-facing) and/or back sides of the photovoltaic cell.

In addition to the pn junctions, a solar cell may include additional layers for improving the efficiency of the photovoltaic cell. For example, highly-doped (e.g. n+ or p+) semiconductor material may be deposited on each surface of the photovoltaic cell before the deposition of the electrical contacts to improve electrical contact between the photovoltaic cell and the electrical contacts.

Most solar cells include a metallic structure (e.g., in a form of a grid) deposited on the side exposed to the solar radiation. Traditionally, the structured layer is screen-printed on the semiconductor substrate. The structured layer may include a plurality of thin straight lines; refer hereinafter as finger electrode(s) and wider conducting lines, refer hereinafter as bus bars (or bus lines or bus strips). The width of the finger electrodes may be small so as to minimize shading of the pn junction. For example, finger electrodes may have a width of 100-120 μm. The width of the bus bars determined such that the electricity generated in the photovoltaic cell and collected by the finger electrodes may be efficiently conducted. The bus bars may be deposited across (typically at right angles to) the finger electrodes

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 is a schematic illustration of an exemplary solar cell according to some embodiments of the invention;

FIG. 2A is a schematic illustration of an exemplary solar cell according to some embodiments of the invention;

FIG. 2B is an illustration of a top view the exemplary solar cell of FIG. 2A according to some embodiments of the invention;

FIG. 3 is a schematic illustration of an exemplary solar cell according to some embodiments of the invention; and

FIG. 4 illustrates a method of producing a solar cell according to some embodiments of the invention.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF EMBODIMENTS

In the following detailed description, numerous specific details are set forth in order to provide a thorough understanding of the invention. However, it will be understood by those skilled in the art that the present invention may be practiced without these specific details. In other instances, well-known methods, procedures, and components, modules, units and/or circuits have not been described in detail so as not to obscure the invention. Some features or elements described with respect to one embodiment may be combined with features or elements described with respect to other embodiments. For the sake of clarity, discussion of same or similar features or elements may not be repeated.

Although embodiments of the invention are not limited in this regard, the terms “plurality” and “a plurality” as used herein may include, for example, “multiple” or “two or more”. The terms “plurality” or “a plurality” may be used throughout the specification to describe two or more components, devices, elements, units, parameters, or the like. Unless explicitly stated, the method embodiments described herein are not constrained to a particular order or sequence. Additionally, some of the described method embodiments or elements thereof can occur or be performed simultaneously, at the same point in time, or concurrently.

In accordance with some embodiments of the present invention, a solar cell may include a layer comprising electrically conducting material deposited on a semiconductor substrate in the form of a structure, or a pattern. The structure may be deposited on the surface of a substrate using, for example, inkjet printing. The structure (or pattern) may include lines of conducting material that cross at intersections. The amount of conducting material deposited on the substrate may be reduced by reducing the height of some of the lines included in the structure. For example, the conductive structure may include at least one bus bar and a plurality of finger electrodes. In some embodiments, the height of the bus bar may be reduced. Further reduction in the amount of deposited material may be achieved by dividing the lines comprising the structure into shorter segments.

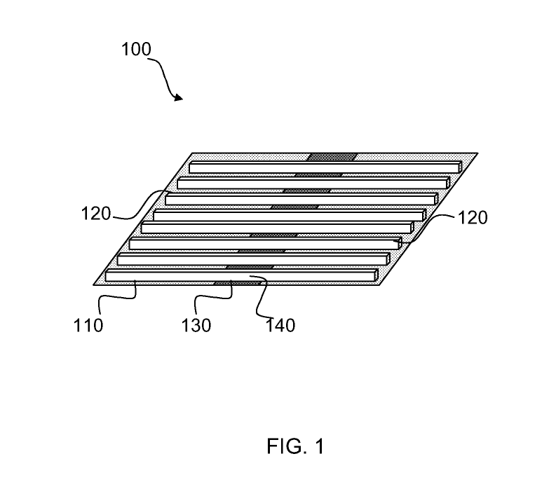

Reference is made to FIG. 1 illustrating an isometric view of an exemplary solar cell according to some embodiments of the invention. A solar cell 100 may include a semiconductor substrate 110 and a conductive structure comprising one or more finger electrodes 120 and a bus bar 130. The one or more finger electrodes are positioned such that least a portion of each finger electrode overlaps bus bars 130 at overlapping portions 140 (i.e., contact areas). Substrate 110 may include for example a silicon photovoltaic wafer. The conducting structure may comprise a plurality of thin finger electrodes 120 and one or more (for example, three) wider bus bars 130. The single bus bar and eight (or eight segmented) finger electrodes illustrated in FIGS. 1-3 are given as an example only. The invention is not limited to any specific number of bus bars of finger electrodes.

Finger electrodes 120 and one or more bus bars 130 (only one is shown) may be deposited on a substrate surface using any material deposition system, for example, an inkjet printing or aerosol jet deposition system. The material deposition system may include a printing head or printing heads that may be configured to first deposit conducting material for at least one bus bars 130 (first layer) and then deposited a conductive material for a plurality of finger electrodes (second layer) such that the portion of the finger electrode overlaps the bus bar may be deposited above the bus bar or vice versa. The finger electrodes may be deposited first, as the first layer, and the bus bar may be deposited above the finger electrode, as the second layer, such that the portion of the finger electrode overlaps the bus bar may be deposited below the bus bar. At the overlapping portions of finger electrodes 120 with bus bar 130, the height of the bus bar is higher than at a non-overlapping portions of the bus bar. The overlapping portions between the bus bars and the finger electrodes constitute a higher structure above the substrate surface, higher than the non-overlapping portions. As a consequence, the bus bar may have an alternating height along the bus's length, responsive to the finger electrodes locations.

In some embodiments, the conductive structure may be inkjet printed on the substrate using a conductive ink The conductive ink may include conductive particle (e.g., metallic nano-particles) dispersed in a liquid medium. For example, the conductive ink may comprise silver nano-particles dispersed in a volatile liquid. Alternatively, the conductive ink may include other conductive particles, for example, copper particles or gold particles. In some embodiments, the formation of each finger electrode and/or bus bar may include depositing/inkjet printing of more than one printed layer. For example, finger electrodes 120 may include ten (10) printed layers of a silver ink deposited one on top of the other.

In some embodiments, the width of the finger electrodes may be smaller than the width of the bus bar(s), as illustrated in FIGS. 1-3. Finger electrodes 120 may have a width smaller than 0.5 mm, for example, 200 μm, 100 μm, 50 μm, or less. One or more bus bars 130 may be deposited substantially perpendicular to the finger electrodes. The width of the bus bars may be larger than 0.5 mm, for example, 0.5 mm, 0.75 mm, 1 mm, 1.5 mm, 2 mm or more.

In some embodiments, the heights of the bus bar, at portions overlapping with the finger electrodes (non-overlapping portions of the bus bar), may be smaller than the height of the finger electrode at portions not overlapping with the bus bar (non-overlapping portions of the finger electrode). For example, the height of bus bar 130 may be 80%, 60%, 50%, 25%, 10% or less of the height of the finger electrodes. The conducting deposited material may include metals (e.g., pure metals, noble metals such as silver, etc.). Depositing conductive structure comprising relatively low bus bar(s) may reduce the amount of the deposited material in comparison to the commonly use deposition technique that comprises printing the bus bars and the finger electrode at substantially the same height. The height is set to ensure that most of the electricity produced in the semi-conductive substrate will be collected by the thin finger electrodes. Reducing the height of the bus bars may not affect the ability of the bus bars to transfer the collected electricity. The reduction of the height of bus bars may reduce the amount of deposited material the by at least: 10%, 25%, 40%, 50% or more.

For example, a typical 6 inch (150 mm) wafer may comprise a deposited conducting silver structure having 85 finger electrodes and 3 bus bars. The finger electrodes may have 105 pm wide and 138 mm long, each and the bus bars may have 1.5 mm wide and 138 mm long. If both the finger electrodes and bus bars are 20 μm high, the amount of silver in the bus bars and the finger electrodes of such wafer may be calculated according to equations (1) and (2).

Finger electrodes: 85×20 [m]×135 [mm]×105 [m]/2×10 [gr/cc]=137 [mgr] (1)

Bus bars: 3×20 [m]×135 [mm]×1500 [μm]×10 [gr/cc]=138 [mgr] (2)

The silver specific weight was estimated to be 10 [gr/cc].

The amount of silver deposited in the bus bars is approximately 50% of all the deposited silver. Reducing the height of the bus bars from 20 μm to 2 μm may result in reduction of 45% of the deposited silver.

In some embodiments, the finger electrodes 120 may be deposited substantially parallel to each other and bus bars 130 may overlap the finger electrodes at overlapping portions 140. Electrical contact may be formed at overlapping portions 140 between bus bars 130 and finger electrodes 120, ensuring that all the electricity collected by the finger electrodes is transferred to the bus bar. In some embodiments, the deposited patterns of the finger electrodes and the bus bar are such that the bus bars cross the finger electrodes at approximately right angles (i.e., the bus bar may be deposited substantially perpendicular to the finger electrodes).

Bus bar 130 may conduct electricity from conducting finger electrodes 120 to an edge of substrate 110. For example, bus bars 130 110 may be connected (e.g. soldered, welded, etc.) to a tab, a ribbon, or other connector (not illustrated). The connector may enable an electrical connection between bus bars 130 and an external device, such as, another solar cell or a device to be electrically powered. In some embodiments, the tab or the ribbon may be soldered to bus bar above the overlapping (contact area 140) and/or non overlapping portions at more than one location.

In some embodiments, the conducting structure may include depositing two layers of materials when depositing the finger electrodes and/or the bus bar. A bottom interface layer (seed layer) may be deposited first on the substrate substantially at the same pattern as the final conductive structure (e.g., a pattern comprising bus bars and finger electrodes). The bottom (seed) layer may include in addition to the conductive ink various portions of adhesion material, for example glass frits. The bottom layer deposited in finger electrodes may include a sufficient amount of glass frits for forming an electrical connection and good adhesion between the semiconductor substrate and the conducting structure. The electrical contact material may be designed to penetrate, when heated, to a conducting layer of the substrate.

In some embodiments, the deposited bus bar may include one or more bottom layers of contacting material. The bottom (seed) layer deposited in the bus bar may be substantially similar or may be different from the bottom layer in the finger electrodes. The bottom layer deposited in the bus bar may include sufficient amount of glass frits for forming good adhesion between the semiconductor substrate. The bottom bus layer may include relatively low concentration of glass frits in comparison to the amount of glass frits in the bottom layer of the finger electrode.

In some embodiments, the finger electrodes may be deposited using a first seed material configured to form a good electrical contact with the substrate (e.g., silicon wafer) and the bus bar(s) may be deposited using a second seed material configured to form a good adhesion with the surface of the substrate. Alternatively, a single electrical contact material may be used to print both the finger electrode and the bus bar. A smaller amount of seed material for one of the crossing contact lines (typically the conducting finger) may be deposited at an intersection zone. Thus, an approximately uniform area density of glass frits, and an approximately uniform penetration depth, may be ensured. After all the seed layer, for both the finger electrodes and the bus bars have been deposited, an upper layer or layers, comprising a conductive ink (e.g., a silver ink) may be deposited on top of the seed layer to form the finger electrodes (using a conductive finger electrode material), and the bus bars (using a conductive bus bar material), such that the overlapping portion comprising a conductive bus material and a conductive finger electrodes material and a good electrical contact (e.g., metal to metal contact) may be achieve between the bus bar(s) and the finger electrodes at the overlapping portions.

In some embodiments, the conductive layer of bus bar 130 may be deposited first on substrate 110 (or on top of a seed layer) and the conductive layer of finger electrodes 120 may be deposited (e.g., printed) above bus bar 130, as illustrated in FIG. 1. In some embodiments, the finger electrode may comprise a first conductive material and the bus bar may comprise a second conductive material, such that in the overlapping portion the first conductive material may be above the second conductive material, or vise versa, in the overlapping portion the first conductive material may be below the second conductive material. In some embodiments, the overlapping portions between the bus bars and the finger electrodes may include direct contact between the conductive layers of the bus bar and the finger electrodes (e.g., metal to metal contact), thus a good electric conduction may be kept between the finger electrodes and the bus bars at overlapping portions 140. In some embodiments, the conductive layer of finger electrodes 120 may be deposited (e.g., printed) first on substrate 110 (or on top of a seed layer) and the one or more bus bars 130 may be deposited (e.g., printed) above the finger electrodes (the finger electrodes are below the bus bar). In this case, the overlapping sections between the bus bars and the finger electrodes have larger overlapping portions 140 than the deposition arrangement illustrated in FIG. 1.

In some embodiments, a metallization may be preformed by inkjet printing. An ink comprising metal particles (e.g., silver nano particles) dispersed in a volatile liquid component (e.g., an organic component) may be deposited on top of the seed layer or the substrate. The deposited ink may further be sintered (i.e., heated to elevated temperature, e.g., 700 Deg C) to evaporate the volatile liquid and to form good electrical contact (e.g., by solid state diffusion) between the metal particles, as to form a solid conductive layer.

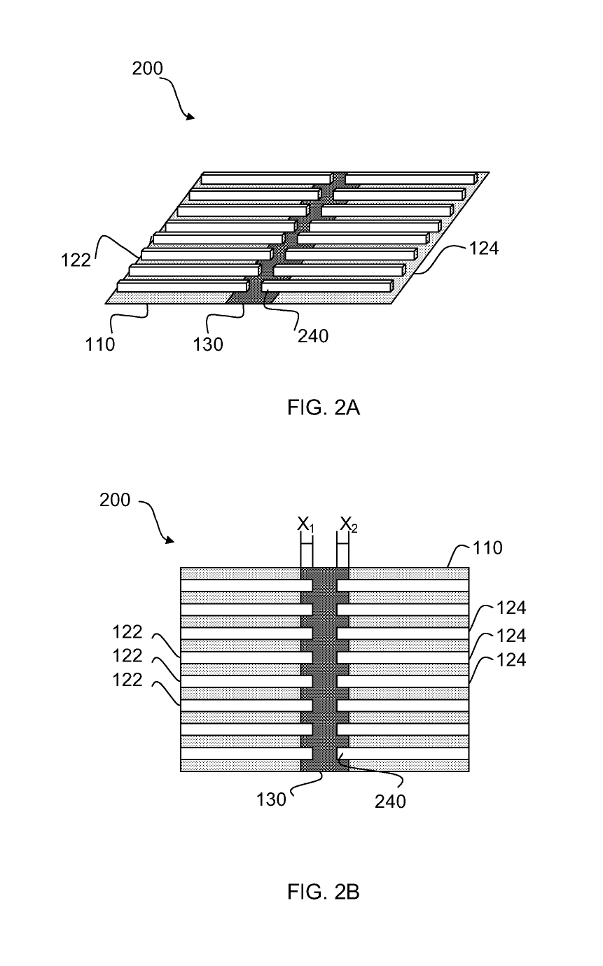

Further reduction of the amount of metal deposited on the substrate may be achieved by depositing the finger electrodes in a segmented configuration such that a segment of a finger electrode, smaller than the width of the bus bar (e.g., smaller than half of the width of the bus bar), overlaps the bus bar. FIGS. 2A and 2B illustrate an isometric view and top view (respectively) of an exemplary solar cell, according to some embodiments of the invention. A solar cell 200 may include a semiconductor substrate 110 and a conductive structure comprising finger electrodes 122 and/or finger electrodes 124 and bus bars 130. A segmented finger electrode may include finger electrode 122 and finger electrode 124 deposited from both side of the bus bar, overlapping with the bus bars at overlapping portions 240 as to create a gap between two overlapping portions 240 of the finger electrode.

Such a conductive structure deposited on substrate 110 may include one or more segmented finger electrodes each including one finger electrode 122 positioned along one side of a bus bar 130 and one finger electrode 124 positioned along the other side of bus bar 130. A segment, having a length of X₁, of finger electrode 122 overlaps the bus bar, such that X₁ is smaller than the width of the bus bar (e.g., smaller than half of the width of the bus bar). X₁ may be determined based on the heights and the width of the finger electrode and optionally the height of the bus bar, such that all the electric current collected in each of finger electrodes 122 may be transfer via overlapping portions 240 to bus bar 130.

X₁ may be determined according to equation (3).

X₁=S_{finger}/2h_{bus bar} (3)

wherein, S_{finger} is the cross section of the finger electrode, and h_{bus bar} is the height of the bus bar. Since the cross section area is often a triangular, S_{finger} can be estimated by S_{finger}=W_{finger}×h_{finger}/2 Wherein, W_{finger} is the bottom width of the finger electrode, and h_{finger} is the height of the finger electrode. For example, if W_{finger}=50 μm; h_{finger}=25 μm; and h_{bus}=2 μm, X₁ is calculated to be 156 μm.

In some embodiments, finger electrodes 124 may be deposited on the other side of bus bar 130, to form with finger electrodes 122 segmented finger electrodes. Finger electrodes 124 may have the same height and width as finger electrodes 122, or may have a different height and width from finger electrode 122, and may further overlaps bus bar 130 in a segment having a length of X₂. Each of finger electrodes 124 may be deposited opposite to one finger electrode 122 on the other side of bus bar 130. In some embodiments, one finger electrode 122 and one finger electrode 124 may form a segmented finger electrode. The segmented finger electrodes may be deposited on the same geometrical axis from two sides of bus bar 130, such that the sum of the segments X₁+X₂ of the finger electrodes 122 and 124 overlapping with bus bar 130, may be smaller than the width of bus bar 130 and a gap may be formed between the finger electrodes, as illustrated in FIGS. 2A and 2B. In some embodiments, the structure may include a plurality of segmented finger electrodes. Finger electrodes 122 and 124 may include substantially the same deposited material, or may be deposited using different materials.

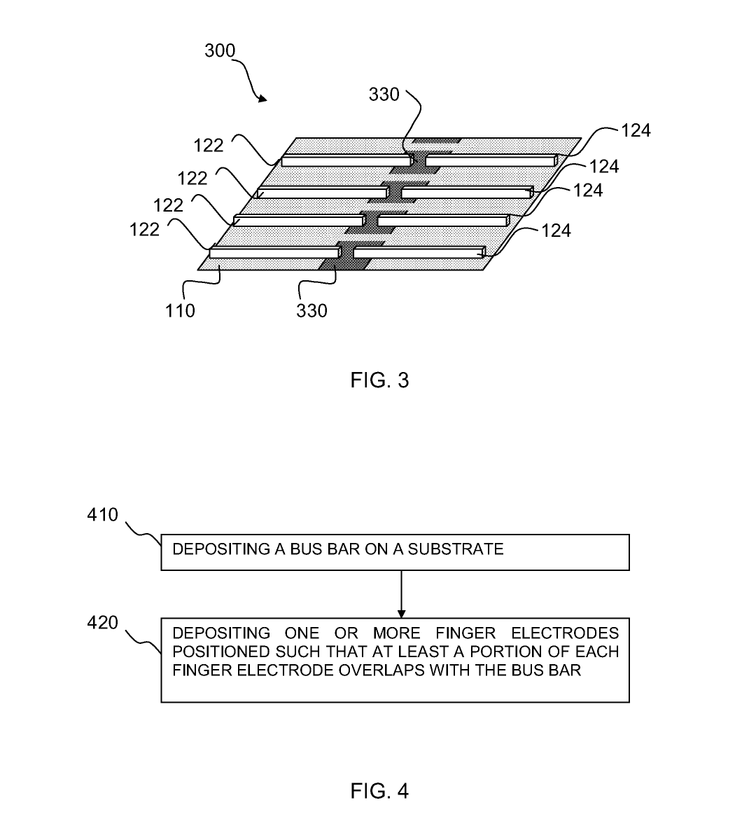

In some embodiments, the bus bar may be divided into segments. Each of the segments may be connected with at least one finger electrode (e.g., finger electrodes 120, 122 or 124) or at least one segmented finger electrodes. Reference is made to FIG. 3 that illustrates an exemplary solar cell according to some embodiments of the invention. The conducting structure may be deposited on substrate 110 may include at least one finger electrode 122 or 124 or a segmented finger electrode comprising finger electrodes 122 and 124 and a plurality of bus bar segments 330. In some embodiments, at least one single continuous finger electrode 120 (not illustrated) may be deposited above (or below) each bus bar segments 330. Each of the finger electrodes or the segmented finger electrodes may overlap with one bus bar segment 330. In some embodiments, the finger electrodes may overlap with the bus bar such that a segment of a finger electrode, smaller than the width of the bus bar, overlaps a portion of the bus bar. In some embodiments, each of segments 330 may overlap with more than one finger electrode or segmented finger electrodes. In order for the bus bar segments to conduct the electricity collected by the finger electrodes electrical connection must be established between the bus bar segments. In some embodiments, a single wire or ribbon may be soldered to a plurality of segments.

In some embodiments, the height of bus bar segments, at non-overlapping portions of the bus bar, 330 may be less than the height of finger electrodes 120, 122 and/or 124 at non-overlapping portions of the finger electrodes. The height of segments 330 may be 80%, 60%, 50%, 25%, 10%, or less than the height of the finger electrodes.

Reference is now made to FIG. 4 that illustrates a method for depositing a conductive structure on a solar cell according to some embodiments of the invention. In operation 410, the method may include depositing a bus bar on a substrate. At least one bus bar (e.g., bus bars 130 or bus bar segments 330) may be deposited on top of a substrate (e.g., substrate 110). The deposited bus bar may include a conductive (upper) layer comprising a metal (e.g., silver). The conductive layer may be deposited on substrate 110, or may be deposited on top of (bottom) seed layer, deposited on substrate 110, prior to the deposition of the conductive layer. The substrate may be any semiconductor, that when deposited with a conductive structure, is configured to produce electricity when expose to electromagnetic radiation (e.g., solar light). The height of the bus bar may be smaller than the height of bus bars known in the art, for example less than 3 μm.

In some embodiments, each of the bus bars deposited, in operation 410, may be printed in segments (e.g., bus bar segments 330).

In operation 420, the method may include depositing one or more finger electrodes (e.g., finger electrodes 120, 122 or 124 or segmented finger electrodes comprising electrodes 124 and 122) on the substrate, such that for each finger electrode least a portion of the finger electrode overlaps the bus bar. In such case, depositing the conductive structure may include first depositing the bas bar and then depositing the one or more finger electrodes. At overlapping portions of the finger electrodes with the bus bar, the height of the bus bar may be higher than at non overlapping portions of the bus bar. In some embodiments, depositing the one or more finger electrodes (e.g., finger electrodes 122 and 124) may includes depositing above the bus bar (e.g., bus bar 130 or bus bar segments 330) one or more segments of a finger electrode, each segment is smaller than the width of the bus bar and overlaps a portion of the bus bar from at least one side of the bus bar. In some embodiments, the size of the segment may be determined based on height of the bus and/or the height of the finger electrode and/or the width of the finger electrode. The finger electrodes may be included in a conductive structure deposited on the substrate. The deposited finger electrode(s) may include a conductive (upper) layer comprising a metal (e.g., silver). The conductive layer may be deposited on substrate 110, or may be deposited on top of a seed (bottom) layer, deposited prior to the deposition of the conductive layer. The seed layer may be configured to form an electrical contact between the semiconductor substrate and the one or more finger electrodes. The height of the bus bar may be less than the height of the finger electrodes at the non-overlapping portions. For example, the height of the bus bar, at portions not overlapping with the one or more finger electrodes, may be 80%, 70%, 50%, 10% or less, than the height of the finger electrode, at portions not overlapping with the bus bar.

In some embodiments, operation 420 may be performed before operation 410 and depositing the conductive structure may include first depositing the one or more finger electrodes and then depositing the bus bar.

The deposited finger electrodes may be substantially parallel to each other. In some embodiments, the bus bar may be deposited substantially perpendicular to the one or more finger electrodes. The bus bar(s) and the finger electrode(s) may be deposited using inkjet printing. In some embodiments, the seed layer and/or the conducting layer may be deposited using inkjet printing. A printing head comprising one or more nozzles may deposit on the substrate both the finger electrodes and the bus bars using ink that includes a volatile liquid and metal particles. A substrate comprising the conducting layer of both the bus bar(s) and the finger electrodes may be introduced into a furnace in order to sinter the conducting layer.

While certain features of the invention have been illustrated and described herein, many modifications, substitutions, changes, and equivalents may occur to those skilled in the art. It is, therefore, to be understood that the appended claims are intended to cover all such modifications and changes as fall within the true spirit of the invention.

1. A solar cell, comprising:
a substrate; and
an electrically conductive structure disposed on the substrate, wherein the structure comprises:
a bus bar; and
one or more finger electrodes positioned such that at least a portion of a finger electrode overlaps the bus bar.

2. The solar cell of claim 1, wherein an overlapping portion of the finger electrode and the bus bar is higher than a non-overlapping portion of the bus bar.

3. The solar cell of claim 2, wherein the overlapping portion comprises a first layer of finger material and a second layer of bus bar material, deposited on top of the first layer.

4. The solar cell of claim 1, wherein the height of non-overlapping portions of the bus bar is smaller than the height of non-overlapping portions of the finger electrodes.

5. The solar cell of claim 1, wherein the finger electrode is segmented so as to create a gap between two overlapping portions of the finger electrode.

6. The solar cell of claim 1, wherein the conductive structure is deposited on the substrate by inkjet printing.

7. The solar cell of claim 1, wherein the bus bar is divided into a plurality of bus bar segments.

8. The solar cell of claim 1, wherein the height of non-overlapping portions of the bus bar is less than 20% of the height of non-overlapping portions of the finger electrode.

9. The solar cell of claim 1, wherein the height of non-overlapping portions of the bus bar is less than 3 μm.

10. The solar cell of claim 2, wherein the overlapping portion comprises a conductive bus material layer and a conductive finger material layer in direct contact.

11. A method of depositing an electrically conductive structure on a solar cell, the method comprising:
depositing a bus bar on a substrate; and
depositing one or more finger electrodes on the substrate, such that for a finger electrode at least a portion of the finger electrode overlaps the bus bar.

12. The method of claim 11, wherein an overlapping portion of finger electrode with bus bar is higher than a non overlapping portion of the bus bar.

13. The method of claim 11, wherein depositing comprises first depositing the one or more finger electrodes and then depositing the bus bar.

14. The method of claim 11, wherein the height of non-over lapping portions of bus bar is smaller than the height of non overlapping portions of the finger electrodes.

15. The method of claim 11, wherein depositing the one or more finger electrodes includes printing a segmented finger electrode so as to create a gap between two overlapping portions of the finger electrode.

16. The method of claim 11, wherein depositing includes inkjet printing.

17. The method of claim 11, wherein depositing the bus bar comprises depositing a plurality of bus bar segments.

18. The method of claim 17, wherein the height of non-overlapping portions of the bus bar is less than 20% of the height of non-overlapping portions of the finger electrode.

19. The method of claim 11, wherein the height of non-overlapping portions of the bus bar is less than 3 μm.
